(19) United States
(12) Patent Application Publication
(10) Pub. No.: US 2026/0122903 A1
(43) Pub. Date: Apr. 30, 2026

(54) THREE-DIMENSIONAL MEMORY DEVICE HAVING CONTACT PLUGS AND FABRICATING METHOD THEREOF

(71) Applicant: SK hynix Inc., Icheon-si (KR)

(72) Inventor: Sung Lae OH, Icheon-si (KR)

(21) Appl. No.: 19/430,512

(22) Filed: Dec. 23, 2025

Related U.S. Application Data
(63) Continuation-in-part of application No. 18/753,606, filed on Jun. 25, 2024.

(30) Foreign Application Priority Data
Feb. 5, 2024 (KR) 10-2024-0017268

(51) Int. Cl. H10B 43/40; H10B 43/10; H10B 43/27; H10B 43/35; H10W 20/00; H10W 20/41; H10W 20/43

(52) U.S. Cl. CPC H10B 43/40; H10B 43/27; H10B 43/35; H10W 20/43; H10W 20/435; H10B 43/10; H10W 20/056

(57) ABSTRACT

A semiconductor device includes a stack including an insulating stack with a plurality of first insulating layers and a plurality of first interlayer insulating layers alternately stacked on a substrate, and an electrode structure including a plurality of electrode layers and a plurality of second interlayer insulating layers alternately stacked on the substrate; a contact plug including a pad portion disposed on the same layer as one electrode layer of the plurality of electrode layers and disposed to contact the one electrode layer, and including a pillar portion extending through the insulating stack to contact the pad portion; and a plurality of hard mask patterns disposed between the pillar portion of the contact plug and some of the plurality of first insulating layers through which the pillar portion extends.

### CROSS-REFERENCE TO RELATED APPLICATION

This application is a continuation-in-part of U.S. application Ser. No. 18/753,606, flied on Jun. 25, 2024, which claims priority under 35 USC § 119 to Korean Patent Application No. 10-2024-0017268 filed in the Korean Intellectual Property Office on Feb. 5, 2024, which is incorporated herein by reference in its entirety.

### BACKGROUND

### 1. Technical Field

Various embodiments of the disclosed technology generally relate to semiconductor technology, and more particularly, to a three-dimensional memory device having contact plugs and a method of fabrication.

### 2. Related Art

A three-dimensional memory device has advantages in that, compared to a conventional device, a larger capacity may be realized within the same area by increasing the number of stacks and vertically stacking memory cells, thereby providing high performance and excellent power efficiency.

In a three-dimensional memory device, electrode layers connected to memory cells are disposed at different heights. In order to independently apply electrical signals to electrode layers disposed at different heights, contact plugs are connected to the respective electrode layers. To this end, methods of forming contact plugs extending to electrode layers by penetrating a stack have been studied.

### SUMMARY

In an embodiment, a three-dimensional memory device may include: a stack including an insulating stack with a plurality of first insulating layers and a plurality of first interlayer insulating layers alternately stacked on a substrate, and an electrode structure including a plurality of electrode layers and a plurality of second interlayer insulating layers alternately stacked on the substrate; a contact plug including a pad portion disposed on the same layer as one electrode layer of the plurality of electrode layers and disposed to contact the one electrode layer, and including a pillar portion extending through the insulating stack to contact the pad portion; and a plurality of hard mask patterns disposed between the pillar portion of the contact plug and some of the plurality of first insulating layers through which the pillar portion extends.

A three-dimensional memory device according to an embodiment includes a stack including a plurality of first insulating layers and a plurality of first interlayer insulating layers alternately stacked on a substrate; a contact plug including a pad portion arranged on the same layer as one of the plurality of first insulating layers and a pillar portion extending through the stack to contact the pad portion; and a plurality of hard mask patterns arranged between the pillar portion of the contact plug and the plurality of first insulating layers. The stack includes an electrode layer disposed on the same layer as one of the plurality of first insulating layers. The pad portion of the contact plug is directly connected to the electrode layer.

### BRIEF DESCRIPTION OF THE DRAWINGS

FIG. 1 is a cross-sectional view of a three-dimensional memory device according to an embodiment of the present disclosure.

FIG. 2 is a plan view illustrating a connection region of FIG. 1.

FIG. 3 is an enlarged view of a part A of FIG. 1.

FIG. 4 is a flow chart showing a method for fabricating a three-dimensional memory device according to an embodiment of the present disclosure.

FIGS. 5 to 13 are cross-sectional views showing a method of fabricating a three-dimensional memory device according to an embodiment of the present disclosure.

FIGS. 14 and 15 are cross-sectional views of a three-dimensional memory device according to embodiments of the present disclosure.

### DETAILED DESCRIPTION

Hereinafter, embodiments of the present disclosure will be described in detail with reference to the accompanying drawings. In the following description, the same elements will be designated by the same reference numerals although they may be shown in different drawings. Further, in the following description of the present disclosure, a detailed description of known functions and configurations incorporated herein will be omitted when it may make the subject matter of the present disclosure rather unclear. It is to be understood that the terms “comprising,” “having,” “including” and so on, used in the description and claims, should not be interpreted as being restricted to the means listed thereafter unless specifically stated otherwise. Where an indefinite or definite article is used when referring to a singular noun, e.g., “a,” “an” and “the,” the singular noun may include a plural of that noun unless specifically stated otherwise.

Also, in describing the components of the disclosure, there may be terms used like first, second, A, B, (a), and (b). These are solely for the purpose of differentiating one component from another component but do not limit the substances, order, sequence or number of the components.

In descriptions for the positional relationships of components, where it is described that at least two components are “connected,” “coupled” or “linked,” it is to be understood that the at least two components may be directly “connected,” “coupled” or “linked” but components may also be indirectly “connected,” “coupled” or “linked” with another component interposed between the two components. Here, another component may be included in at least one of the at least two components which are “connected,” “coupled” or “linked” with each other.

In descriptions of relationships of components, an operating method or a fabricating method with respect to the flow of time, “pre” and “post” relationships in terms of time or “pre” and “post” relationships in terms of flow are described, such as for example using terms “after,” “following,” “next” or “before”. Non-continuous cases may be included unless “immediately” or “directly” is used.

Where a numerical value for a component or its corresponding information is used, even though there is no separate explicit description, the numerical value or its corresponding information can be interpreted as including an error range related to by various factors (for example, a process variable, an internal or external shock, noise, etc.).

Hereinafter, various embodiments of the disclosed technology will be described in detail with reference to the accompanying drawings.

According to the embodiments of the disclosed technology, it is possible to provide a three-dimensional memory device that has contact plugs that penetrate a stack and extending to electrode layers by penetrating a stack.

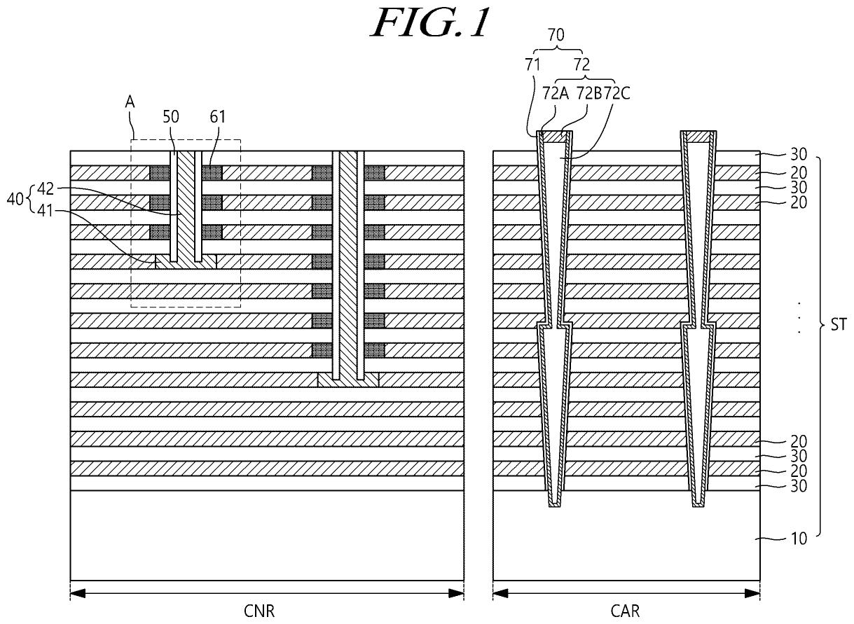

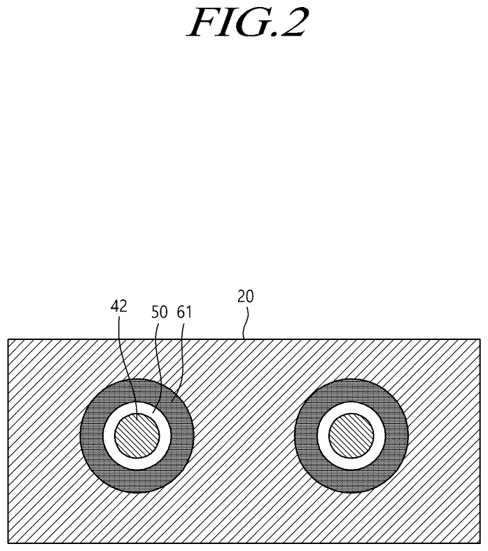

FIG. 1 is a cross-sectional view of a three-dimensional memory device according to an embodiment of the present disclosure, and FIG. 2 is a plan view illustrating a connection region of FIG. 1.

Referring to FIG. 1, a three-dimensional memory device 100 may include a substrate 10. A stack ST may be disposed in a connection region CNR and a cell array region CAR of a substrate 10.

The stack ST may include a plurality of electrode layers 20 and a plurality of interlayer insulating layers 30, which are alternately stacked. The electrode layers 20 may include a conductive material. For example, the electrode layers 20 may include at least one selected from among doped semiconductor (e.g., doped silicon), metal (e.g., tungsten, copper or aluminum), conductive metal nitride (e.g., titanium nitride or tantalum nitride) and transition metal (e.g., titanium or tantalum). The interlayer insulating layers 30 may include oxide, for example, silicon oxide.

The electrode layers 20 may configure row lines. The row lines may include at least one source select line, at least one drain select line, and a plurality of word lines. Among the electrode layers 20, at least one electrode layer 20 from a lowermost electrode layer 20 may configure a source select line, and at least one electrode layer 20 from an uppermost electrode layer 20 may configure a drain select line. Electrode layers 20 between the source select line and the drain select line may configure word lines.

Contact plugs 40 may vertically penetrate through the stack ST in the connection region CNR. Each contact plug 40 may extend to one of the plurality of electrode layers 20 by vertically penetrating the stack ST from the upper surface of the stack ST, and may be electrically connected to the one electrode layer 20.

Each contact plug 40 may include a pad portion 41 and a pillar portion 42. The pad portion 41 may be disposed in the same layer as one of the plurality of electrode layers 20, and may be electrically connected to the one electrode layer 20. A side surface of the pad portion 41 may contact a side surface of the one electrode layer 20.

The pillar portion 42 may extend to the pad portion 41 by vertically penetrating the stack ST to the pad portion 41. The pad portion 41 and the pillar portion 42 may be simultaneously formed. The pad portion 41 and the pillar portion 42 may be provided as an integrated element or structure.

For the sake of simplicity in illustration, FIG. 1 illustrates only two contact plugs 40 connected to two electrode layers 20. However, a plurality of contact plugs 40 may be provided in correspondence to the plurality of electrode layers 20, respectively, and each contact plug 40 may be electrically connected to a corresponding electrode layer 20.

A spacer 50 may be disposed on the side surface of the pillar portion 42. As illustrated in FIG. 2, the spacer 50 may surround the side surface of the pillar portion 42. For example, the pillar portion 42 may have a pillar shape, and the spacer 50 may have a cylindrical or tubular structure that surrounds outer surfaces of the pillar portion 42. An inner surface of the spacer 50 may contact the outer surfaces of the pillar portion 42.

The spacer 50 may include oxide, for example, silicon oxide.

First hard mask patterns 61 may be disposed between the spacer 50 and electrode layers 20 around the spacer 50. The first hard mask patterns 61 may be disposed at the same layers as corresponding electrode layers 20, respectively.

As illustrated in FIG. 2, each of the first hard mask patterns 61 may be provided to surround an outer surface of the spacer 50. For example, the spacer 50 may have a cylindrical or tubular structure, and the first hard mask pattern 61 may have a cylindrical or tubular structure that surrounds the outer surface of the spacer 50. The inner surface of the first hard mask pattern 61 may contact an outer surface of the spacer 50.

The first hard mask patterns 61 may have a different etch selectivity from the spacer 50 and the interlayer insulating layers 30. For example, the spacer 50 and the interlayer insulating layers 30 may include oxide such as silicon oxide, and the first hard mask patterns 61 may include a material that has an etch selectivity different from oxide. For example, the first hard mask patterns 61 may include silicon oxynitride (SiON), which is thermally stable and is thus capable of withstanding high temperature without damage.

A plurality of cell plugs 70 may vertically pass through the stack ST in the cell array region CAR and extend into the substrate 10. Each cell plug 70 may include a memory pattern 71 and a channel structure 72.

Although not illustrated, the memory pattern 71 may include a tunnel insulating layer, a data storage layer and a first blocking insulating layer. The tunnel insulating layer may extend along the surface of the channel structure 72, and may include an insulating material capable of charge tunneling. The data storage layer may extend along the surface of the channel structure 72 with the tunnel insulating layer interposed therebetween. The data storage layer may include a material layer capable of storing data that may be changed, using Fowler-Nordheim tunneling. For example, the data storage layer may include a nitride layer capable of charge trapping, but examples are not limited thereto. The data storage layer may include a phase change material, nanodots, etc. The first blocking insulating layer may extend along the surface of the channel structure 72 with the tunnel insulating layer and the data storage layer interposed therebetween. The first blocking insulating layer may include an insulating material capable of blocking the movement of charges.

The channel structure 72 may include a cell channel layer 72A, a capping pattern 72B and a core insulating pattern 72C. The cell channel layer 72A is used as the channel of a memory cell string. The cell channel layer 72A is disposed on the memory pattern 71, and may be formed of a semiconductor material. For example, the cell channel layer 72A may include silicon. The capping pattern 72B and the core insulating pattern 72C may fill the central region of the channel structure 72. The core insulating pattern 72C may include oxide. The capping pattern 72B may be disposed on the core insulating pattern 72C, and may include a sidewall that is surrounded by the upper end portion of the cell channel layer 72A. The capping pattern 72B may include a doped semiconductor layer that includes at least one of an n-type impurity or a p-type impurity.

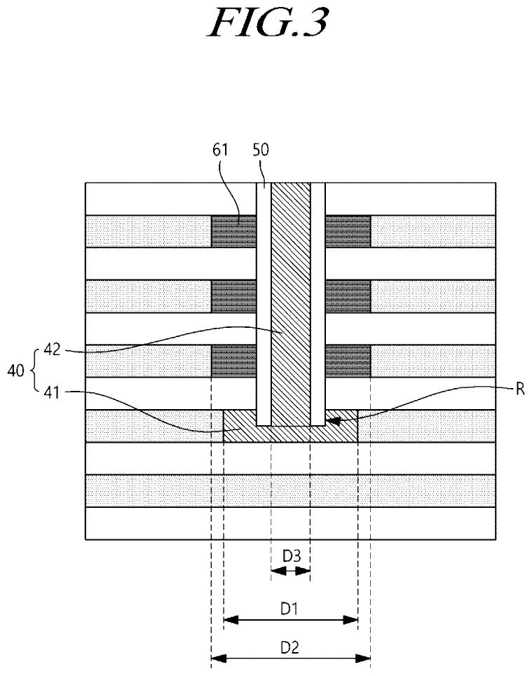

FIG. 3 is an enlarged view of a part A of FIG. 1.

Referring to FIG. 3, a horizontal dimension of a pad portion 41 of a contact plug 40 may be different from a horizontal dimension of a first hard mask pattern 61. As illustrated in FIG. 3, the horizontal dimension of the pad portion 41 is D1, the horizontal dimension of the first hard mask pattern 61 is D2, and D1 may be smaller than D2. The pad portion 41 may have a horizontal dimension smaller than the first hard mask pattern 61.

The horizontal dimension of the pad portion 41 of the contact plug 40 may be different from a horizontal dimension of a pillar portion 42 of the contact plug 40. As illustrated in FIG. 3, the horizontal dimension of the pad portion 41 is D1, the horizontal dimension of the pillar portion 42 is D3, and D1 may be larger than D3. The pad portion 41 may have a horizontal dimension larger than the pillar portion 42.

The pad portion 41 may include a recess R on an upper surface. The recess R may penetrate the upper surface of the pad portion 41. A spacer 50 may be disposed on a side surface of the recess R, and the pillar portion 42 may be disposed in a central region of the recess R. Within the recess R, the pillar portion 42 may be surrounded by the spacer 50. Although FIG. 3 illustrates a pad portion 41 provided with a recess R on an upper surface, the disclosed technology is not limited thereto, and in other embodiments the recess R may be omitted.

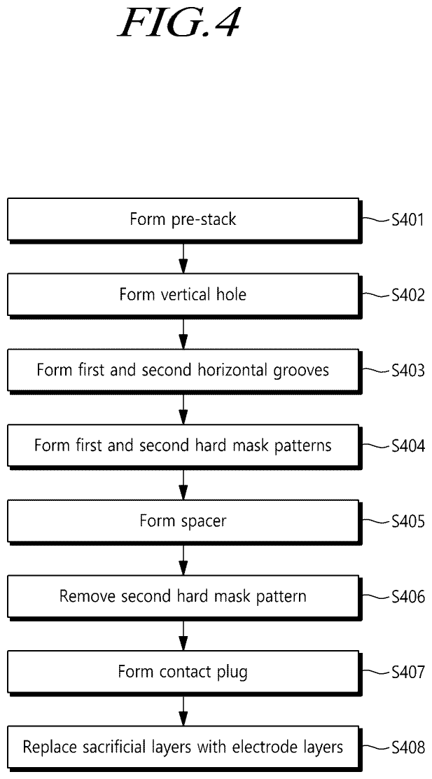

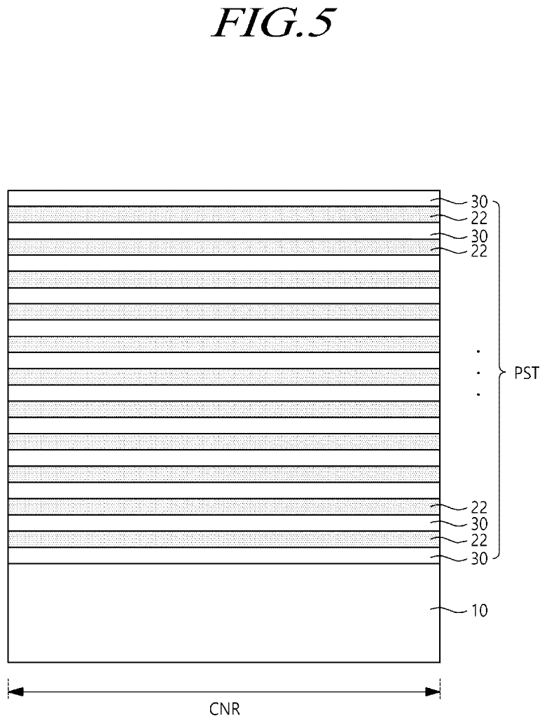

FIG. 4 is a flow chart showing a method for fabricating a three-dimensional memory device according to an embodiment of the present disclosure, and FIGS. 5 to 13 are cross-sectional views showing a method of fabricating a three-dimensional memory device according to an embodiment of the present disclosure.

Referring to FIGS. 4 and 5, a step of forming a pre-stack PST may be performed (S401). Although FIGS. 5 to 13 only show that the pre-stack PST is formed in the connection region CNR. Although not shown, the pre-stack PST is formed in the cell region as well as the connection region CNR.

The pre-stack PST may be formed by alternately stacking a plurality of sacrificial layers 22 and a plurality of interlayer insulating layers 30 on a substrate 10. The sacrificial layers 22 and the interlayer insulating layers 30 may have different etch selectivities. The interlayer insulating layers 30 may include oxide, such as for example silicon oxide, and the sacrificial layers 22 may include a material that has an etch selectivity different from oxide, such as for example nitride in silicon nitride.

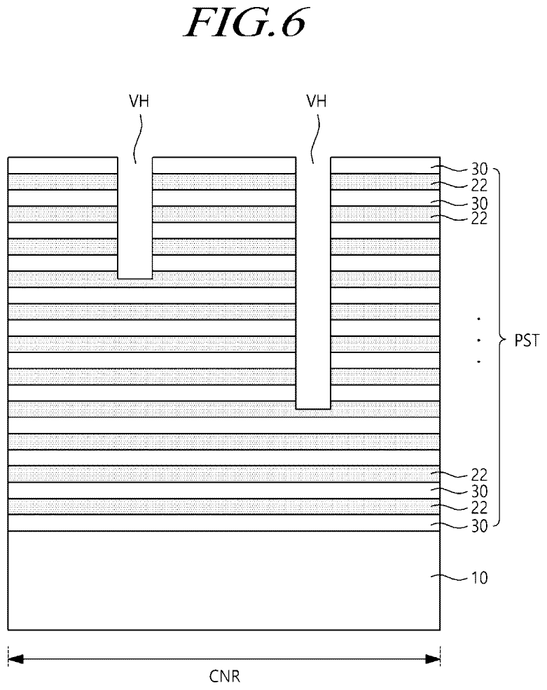

Referring to FIGS. 4 and 6, a step of forming vertical holes VH may be performed (S402).

Each vertical hole VH may extend into one of the plurality of sacrificial layers 22 by penetrating the pre-stack PST from an upper surface of the pre-stack PST. For the sake of simplicity in illustration, only two vertical holes VH are illustrated in FIG. 6, but a plurality of vertical holes VH may be formed that correspond respectively to some of the plurality of the sacrificial layers 22.

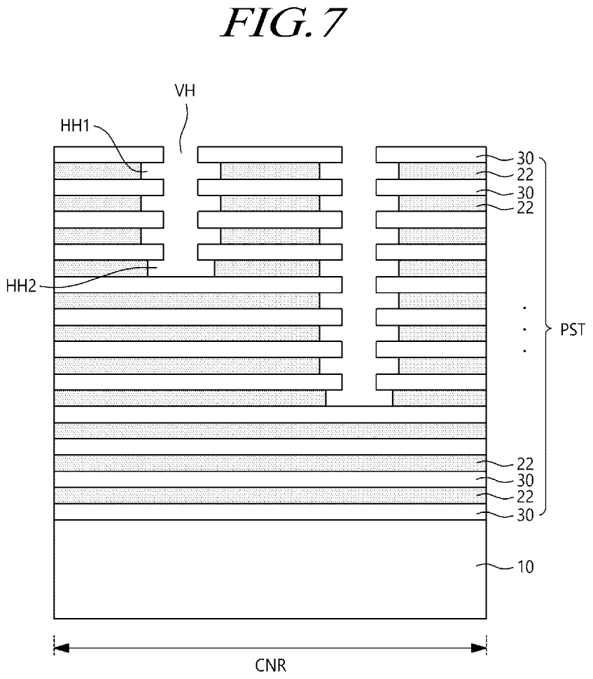

Referring to FIGS. 4 and 7, a step of forming first and second horizontal grooves HH1 and HH2 may be performed (S403).

The first horizontal grooves HH1 and the second horizontal groove HH2 may be formed by selectively removing portions of sacrificial layers 22 that are exposed by the vertical hole VH. The first horizontal grooves HH1 may be connected to side surfaces of the vertical hole VH. The second horizontal groove HH2 may be connected to a lower end portion of the vertical hole VH.

The first and second horizontal grooves HH1 and HH2 may be formed using an isotropic etching process with an etchant capable of selectively removing the sacrificial layers 22.

The first horizontal grooves HH1 may extend in the horizontal direction from side surfaces of the vertical hole VH. The second horizontal groove HH2 may extend in the horizontal direction from a center portion of the lowermost sacrificial layer 22 common to vertical hole VH. Accordingly, the first horizontal groove HH1 and the second horizontal groove HH2 may have different dimensions. The second horizontal groove HH2 may have a cross-sectional dimension that is smaller than the first horizontal groove HH1.

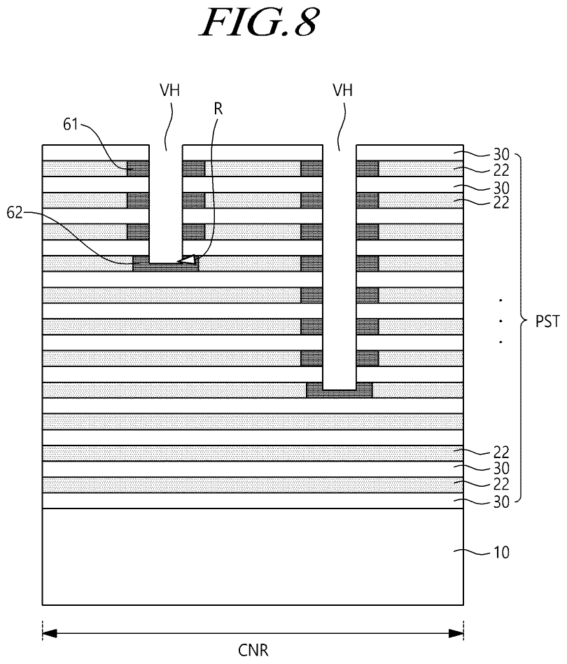

Referring to FIGS. 4 and 8, a step of forming first and second hard mask patterns 61 and 62 may be performed (S404).

A hard mask layer may be formed to fill the first and second horizontal grooves HH1 and HH2. The hard mask layer may have an etch selectivity different from the sacrificial layers 22 and the interlayer insulating layers 30. For example, the interlayer insulating layers 30 may include oxide (e.g., silicon oxide), the sacrificial layers 22 may include nitride (e.g., silicon nitride), and the hard mask layer may include a material that has an etch selectivity different from oxide and nitride. For example, the hard mask layer may include silicon oxynitride (SiON).

By removing the hard mask layer formed outside of the first and second horizontal grooves HH1 and HH2, the first hard mask patterns 61 may be formed in the first horizontal grooves HH1, and the second hard mask pattern 62 may be formed in the second horizontal groove HH2, while the vertical holes VH from FIG. 6 are substantially re-established.

While the first horizontal groove HH1 is completely filled with the hard mask layer, the central region of the second horizontal groove HH2 may be left partially unfilled, so that a recess R may be formed on an upper surface of the second hard mask pattern 62. Although FIG. 8 illustrates a recess R formed on the upper surface of the second hard mask pattern 62, the disclosed technology is not limited thereto, and in other embodiments the recess R may not be formed.

Referring to FIGS. 4, 9 and 10, a step of forming spacers 50 may be performed (S405).

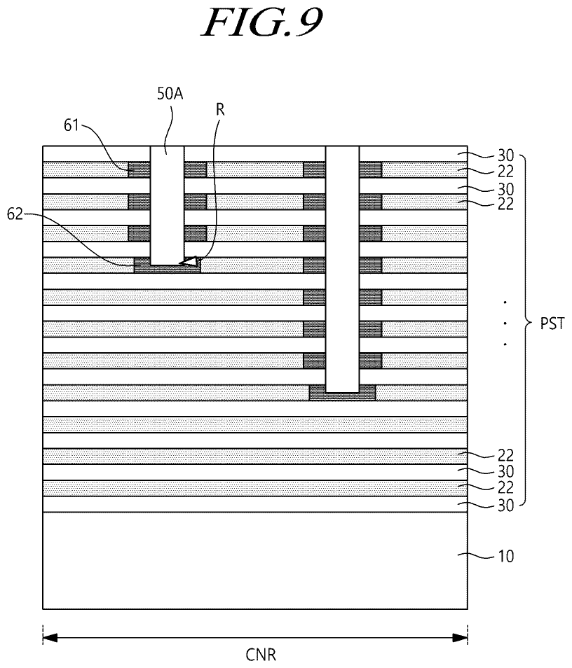

An insulating layer 50A may be formed in the vertical holes VH. As illustrated in FIG. 9, the insulating layer 50A may be formed to completely fill a vertical hole VH. However, in other embodiments, the insulating layer 50A may be formed to cover the side surfaces of the vertical hole VH and only partially fill the central region of the vertical hole VH.

The insulating layer 50A may have an etch selectivity different from the sacrificial layers 22 and the second hard mask pattern 62. For example, the sacrificial layers 22 may include nitride (e.g., silicon nitride), the second hard mask pattern 62 may include silicon oxynitride (SiON), and the insulating layer 50A may include an insulating material that has an etch selectivity different from nitride and silicon oxynitride (SiON). For example, the insulating layer 50A may include oxide (e.g., silicon oxide).

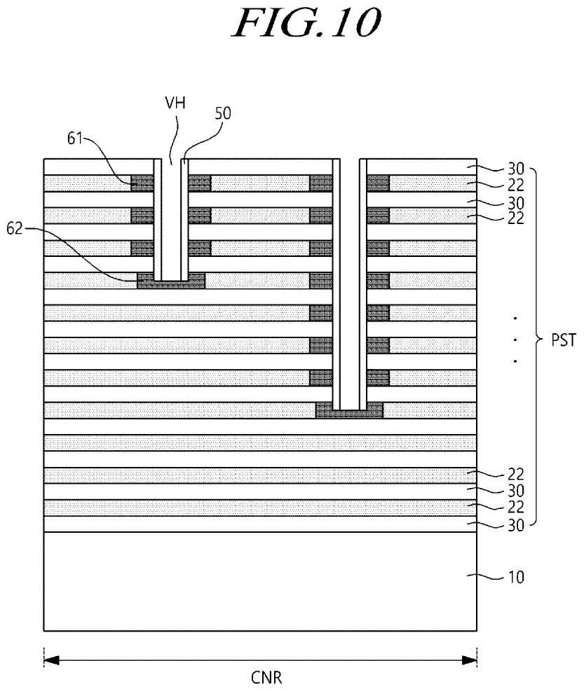

As illustrated in FIG. 10, through an etching process using the second hard mask pattern 62 as an etch stopper, the insulating layer 50A in the central region of the vertical hole VH may be removed, leaving an insulating layer 50A on the side surfaces of the vertical hole VH. In this manner, a cylindrical or tubular shaped spacer 50 may be formed that extends into the second hard mask pattern 62.

Due to the difference in etch selectivity between the insulating layer 50A and the second hard mask pattern 62, etching during an etching process for removing the insulating layer 50A in the central region of the vertical hole VH may be stopped at the second hard mask pattern 62, by which it is possible to prevent the sacrificial layers 22 and the interlayer insulating layers 30 under the second hard mask pattern 62 from being etched. In other words, over-etching may be prevented.

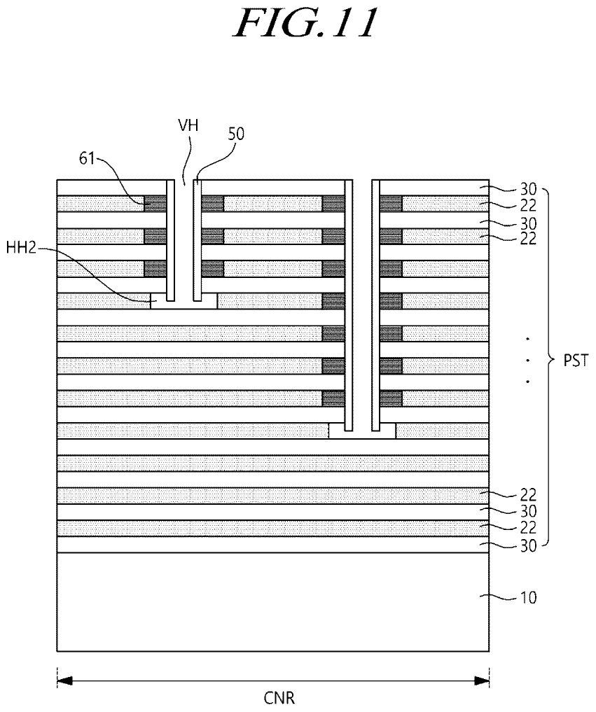

Referring to FIGS. 4 and 11, a step of removing the second hard mask pattern 62 may be performed (S406).

The second hard mask pattern 62 may be removed using an etchant capable of selectively removing the second hard mask pattern 62.

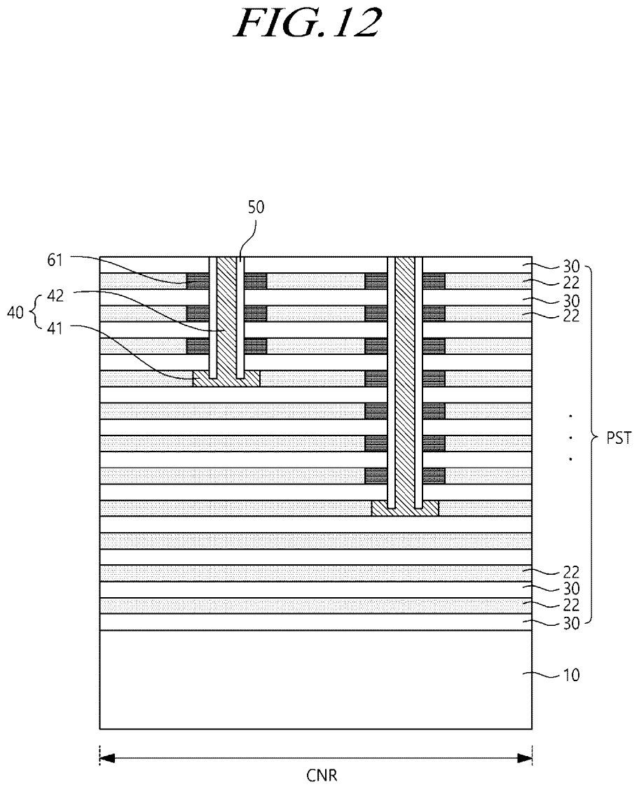

Referring to FIGS. 4 and 12, a step of forming contact plugs 40 may be performed (S407).

A contact plug 40 may be formed of a conductive material that fills the second horizontal groove HH2 and the central region of the vertical hole VH exposed due to removal of the second hard mask pattern 62. The contact plug 40 may include a pad portion 41 that fills the second horizontal groove HH2 and a pillar portion 42 that fills the central region of the vertical hole VH.

The pad portion 41 and the pillar portion 42 may be formed by growing or depositing, at the same or substantially the same time, a conductive material in the central region of the vertical hole VH and the second horizontal groove HH2. Accordingly, the pad portion 41 and the pillar portion 42 may be integrally formed.

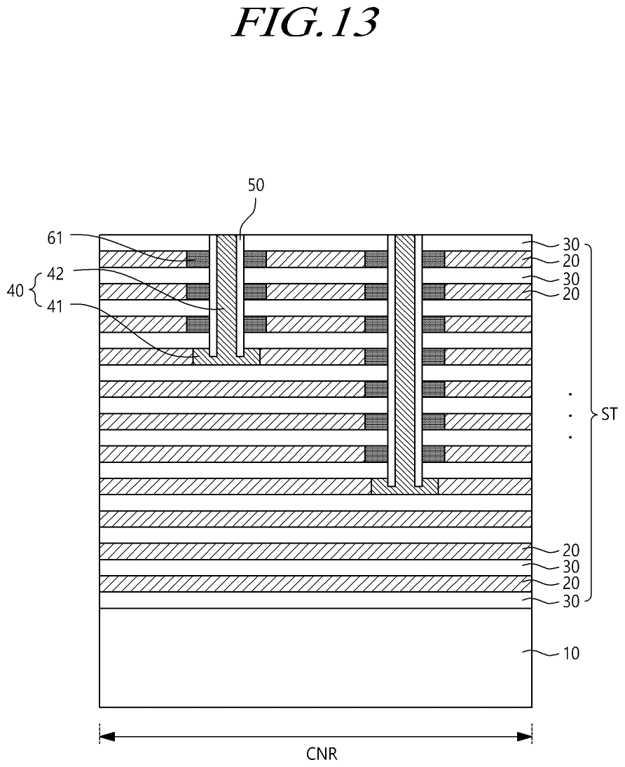

Referring to FIGS. 4 and 13, a step of replacing the sacrificial layers 22 with electrode layers 20 is performed (S408).

By selectively removing the sacrificial layers 22 and filling empty regions created due to removal of the sacrificial layers 22 with an electrode material, the electrode layers 20 are formed.

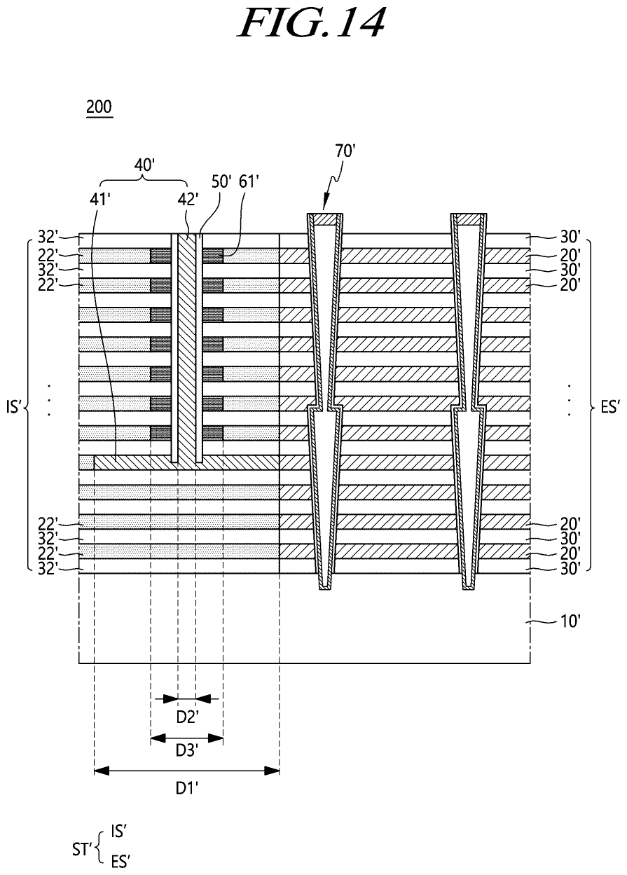

FIG. 14 is a cross-sectional view of a three-dimensional memory device according to an embodiment of the present disclosure.

For simplicity, redundant descriptions of components identical to those previously described with reference to FIGS. 1 to 13 will be omitted.

Referring to FIG. 14, a three-dimensional memory device 200 includes a substrate 10′, a stack ST′, a contact plug 40′, a spacer 50′, a first hard mask pattern 61′, and a cell plug 70′.

The stack ST′ may be disposed on the substrate 10′. The stack ST′ may include an electrode stack ES' and an insulating stack IS′. The electrode stack ES' may include a plurality of electrode layers 20′ and a plurality of first interlayer insulating layers 30′ vertically and alternately stacked on the substrate 10′. The insulating stack IS' may include a plurality of first insulating layers 22′ and a plurality of second interlayer insulating layers 32′ vertically and alternately stacked on a substrate 10′.

The first insulating layers 22′ may be disposed on the same layers as the electrode layers 20′. The second interlayer insulating layers 32′ may be disposed on the same layers as the first interlayer insulating layers 30′. The first interlayer insulating layers 30′ and the second interlayer insulating layers 32′ disposed on the same layer may be integrally formed in the same layer.

The first interlayer insulating layers 30′ and the second interlayer insulating layers 32′ may include the same insulating material. The first insulating layers 22′ may include an insulating material having different etch selectivity from the first interlayer insulating layers 30′ and the second interlayer insulating layers 32′. The first interlayer insulating layers 30′ and the second interlayer insulating layers 32′ may include an oxide, and the first insulating layers 22′ may include a nitride. The oxide may include silicon oxide, and the nitride may include silicon nitride.

The contact plug 40′ may include a pad portion 41′ and a pillar portion 42′. The pad portion 41′ may be arranged on the same layer as one of the plurality of first insulating layers 22′ and one of the plurality of electrode layers 20′. The pad portion 41′ may extend horizontally and be connected to the one electrode layer 20′. The pad portion 41′ may be in contact with the one electrode layers 20′.

The pillar portion 42′ may extend to the pad portion 41′ by vertically penetrating the insulating stack IS′. The pad portion 41′ and the pillar portion 42′ may be formed simultaneously. The pad portion 41′ and the pillar portion 42′ may be formed integrally as a continuous structure.

A horizontal dimension of the pad portion 41′ may be different from a horizontal dimension of the pillar portion 42′. The horizontal dimension of the pad portion 41′ may be greater than the horizontal dimension of the pillar portion 42′. As illustrated in FIG. 14, the horizontal dimension of the pad portion 41′ is D1′, and the horizontal dimension of the pillar portion 42′ is D2′. D1′ is larger than D2′.

For simplicity, FIG. 14 only illustrates one contact plug 40′ connected to one electrode layer 20′, but a plurality of contact plugs may be provided with pad portions corresponding to each of a plurality of electrode layers, and each contact plug may be connected to a corresponding electrode layer through a pad portion.

The spacer 50′ may be disposed on a side of the pillar portion 42′ of the contact plug 40′. The spacer 50′ may surround an outer surface of the pillar portion 42′ of the contact plug 40′. The pillar portion 42′ of the contact plug 40′ may have a cylindrical shape, and the spacer 50′ may have a cylindrical structure that surrounds the outer surface of the pillar portion 42′ of the contact plug 40′. The inner surface of the spacer 50′ may be in contact with the outer surface of the pillar portion 42′ of the contact plug 40′.

The first hard mask patterns 61′ may be disposed between the spacer 50′ and the first insulating layers 22′. The first hard mask patterns 61′ correspond to some of the plurality of the first insulating layers 22′, respectively, and each first hard mask pattern 61′ may be disposed on the same layer as a corresponding first insulating layer 22′.

The first hard mask pattern 61′ may surround the outer surface of the spacer 50′. The spacer 50′ may have a cylindrical structure, and the first hard mask pattern 61′ may have a cylindrical structure surrounding the outer surface of the spacer 50′. The outer surface of the first hard mask pattern 61′ may contact the corresponding first insulating layer 22′, and the inner surface of the first hard mask pattern 61′ may contact the spacer 50′.

The first hard mask patterns 61′ may have different etch selectivities from the spacers 50′, the first interlayer insulating layers 30′, and the second interlayer insulating layers 32′. For example, the spacers 50′, the first interlayer insulating layers 30′, and the second interlayer insulating layers 32′ may include oxide, and the first hard mask patterns 61′ may include silicon oxynitride.

The horizontal dimension of the pad portion 41′ of the contact plug 40′ may be different from the horizontal dimension of the first hard mask pattern 61′. The horizontal dimension of the pad portion 41′ of the contact plug 40′ may be greater than the horizontal dimension of the first hard mask pattern 61′. As illustrated in FIG. 14, the horizontal dimension of the pad portion 41′ is D1′, and the horizontal dimension of the first hard mask pattern 61′ is D3′. D1′ is larger than D3′.

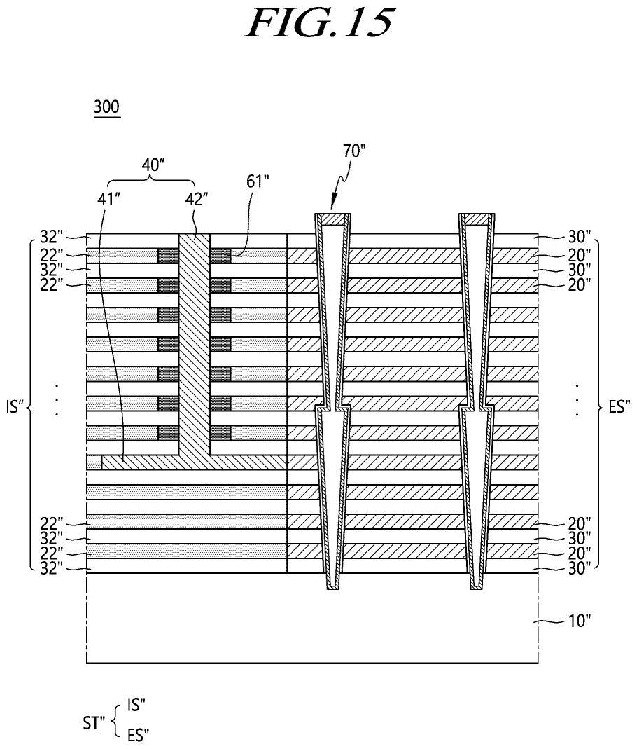

FIG. 15 is a cross-sectional view of a three-dimensional memory device according to an embodiment of the present disclosure.

For simplicity, redundant descriptions of the same components as those described with reference to FIGS. 1 to 14 will be omitted.

Referring to FIG. 15, a three-dimensional memory device 300 according to an embodiment of the present disclosure includes a substrate 10″, a stack ST″, a contact plug 40″, a first hard mask pattern 61″, and a cell plug 70″.

The stack ST″ may be disposed on the substrate 10″. The stack ST″ may include an electrode stack ES″ and an insulating stack IS″. The electrode stack ES″ may include a plurality of electrode layers 20″ and a plurality of first interlayer insulating layers 30″ that are alternately stacked. The insulating stack IS″ may include a plurality of first insulating layers 22″ and a plurality of second interlayer insulating layers 32″ that are alternately stacked.

The contact plug 40″ may include a pad portion 41″ and a pillar portion 42″. The pad portion 41″ may be disposed on the same layer as one of the plurality of first insulating layers 22″ and one of the plurality of electrode layers 20″. The pad portion 41″ may extend horizontally and be connected to the one electrode layer 20″. The pad portion 41″ may contact the one electrode layer 20″. The pillar portion 42″ may extend vertically through the insulating stack IS″ to contact the pad portion 41″.

The first hard mask patterns 61″ may be disposed between the pillar portion 42″ and the first insulating layers 22″ of the contact plug 40″. The first hard mask patterns 61″ correspond to some of the plurality of first insulating layers 22″, respectively, and each hard mask pattern 61″ may be arranged on the same layer as a corresponding first insulating layer 22″, respectively.

The first hard mask pattern 61″ may surround_the outer surface of the pillar portion 42″ of the contact plug 40″. The pillar portion 42″ of the contact plug 40″ may have a cylindrical structure, and the first hard mask pattern 61″ may have a cylindrical structure that surrounds the outer surface of the pillar portion 42″ of the contact plug 40″.

The outer surface of the first hard mask pattern 61″ may be in contact with the corresponding first insulating layer 22″, and the inner surface of the first hard mask pattern 61″ may be in contact with the pillar portion 42″ of the contact plug 40″.

Although exemplary embodiments of the present disclosure have been described for illustrative purposes, those skilled in the art will appreciate that various modifications, additions and substitutions are possible, without departing from the scope and spirit of the present disclosure. Therefore, the embodiments disclosed above and in the accompanying drawings should be considered in a descriptive sense only and not for limiting the technological scope. The technological scope of the present disclosure is not limited by the embodiments and the accompanying drawings.

What is claimed is:

1. A three-dimensional memory device comprising:
a stack including an insulating stack with a plurality of first insulating layers and a plurality of first interlayer insulating layers alternately stacked on a substrate, and an electrode structure including a plurality of electrode layers and a plurality of second interlayer insulating layers alternately stacked on the substrate;
a contact plug including a pad portion disposed on the same layer as one electrode layer of the plurality of electrode layers and disposed to contact the one electrode layer, and including a pillar portion extending through the insulating stack to contact the pad portion; and
a plurality of hard mask patterns disposed between the pillar portion of the contact plug and some of the plurality of first insulating layers through which the pillar portion extends.

2. The three-dimensional memory device of claim 1, wherein the plurality of hard mask patterns have different etch selectivities from the first interlayer insulating layers and the second interlayer insulating layers.

3. The three-dimensional memory device of claim 1, wherein the first interlayer insulating layers and the second interlayer insulating layers include oxide, and the plurality of hard mask patterns include silicon oxynitride.

4. The three-dimensional memory device of claim 1, wherein the plurality of hard mask patterns are configured to surround an outer surface of the pillar portion of the contact plug.

5. The three-dimensional memory device of claim 1, wherein the plurality of hard mask patterns correspond to some of the plurality of first insulating layers through which the pillar portion extends, respectively, and are disposed between the corresponding first insulating layer and the pillar portion of the contact plug.

6. The three-dimensional memory device of claim 5, wherein each of the plurality of hard mask patterns is in contact with a corresponding first insulating layer and the pillar portion of the contact plug.

7. The three-dimensional memory device of claim 1, further comprising a spacer surrounding an outer surface of the pillar portion of the contact plug,
wherein the plurality of hard mask patterns are configured to surround an outer surface of the spacer.

8. The three-dimensional memory device of claim 7, wherein the plurality of hard mask patterns correspond to some of the plurality of first insulating layers through which the pillar portion extends, respectively, and are disposed between the corresponding first insulating layers and the spacer.

9. The three-dimensional memory device of claim 8, wherein each of the plurality of hard mask patterns is in contact with a corresponding first insulating layer and the spacer.

10. The three-dimensional memory device of claim 7, wherein the spacer has different etch selectivity from the plurality of hard mask patterns.

11. The three-dimensional memory device of claim 10, wherein the spacer includes an oxide, and the plurality of hard mask patterns include silicon oxynitride (SiON).

12. The three-dimensional memory device of claim 1, wherein the pad portion of the contact plug has a horizontal dimension greater than a horizontal dimension of the pillar portion of the contact plug.

13. The three-dimensional memory device of claim 1, wherein the pad portion of the contact plug has a horizontal dimension greater than a horizontal dimension of each of the plurality of hard mask patterns.

14. The three-dimensional memory device of claim 1, wherein the pad portion of the contact plug and the pillar portion of the contact plug are portions of a continuous structure.

15. The three-dimensional memory device of claim 1, wherein the plurality of first interlayer insulating layers correspond to the plurality of second interlayer insulating layers, respectively, and are arranged respectively on the same layers as the corresponding plurality of second interlayer insulating layers.

16. A three-dimensional memory device comprising:
a stack including a plurality of first insulating layers and a plurality of first interlayer insulating layers alternately stacked on a substrate;
a contact plug including a pad portion arranged on the same layer as one of the plurality of first insulating layers and a pillar portion extending through the stack to contact the pad portion; and
a plurality of hard mask patterns arranged between the pillar portion of the contact plug and the plurality of first insulating layers,
wherein the stack includes an electrode layer disposed on the same layer as one of the plurality of first insulating layers,
wherein the pad portion of the contact plug is directly connected to the electrode layer.

17. The three-dimensional memory device of claim 16, wherein the pad portion of the contact plug has a horizontal dimension greater than a horizontal dimension of the pillar portion of the contact plug.

18. The three-dimensional memory device of claim 16, wherein the pad portion of the contact plug has a horizontal dimension greater than a horizontal dimension of each of the plurality of hard mask patterns.

19. The three-dimensional memory device of claim 16, wherein the plurality of hard mask patterns have different etch selectivities from the first interlayer insulating layers.

20. The three-dimensional memory device of claim 16, wherein the plurality of first insulating layers have different etch selectivities from the first interlayer insulating layers.
